(19) United States
(12) Patent Application Publication
(10) Pub. No.: US 2015/0124543 A1
(43) Pub. Date: May 7, 2015

(54) SEMICONDUCTOR DEVICES

(71) Applicant: SK hynix Inc., Icheon-si Gyeonggi-do (KR)

(72) Inventor: Woo Young LEE, Icheon-si Gyeonggi-do (KR)

(73) Assignee: SK hynix Inc., Icheon-si Gyeonggi-do (KR)

(21) Appl. No.: 14/193,085

(22) Filed: Feb. 28, 2014

(30) Foreign Application Priority Data
Nov. 6, 2013 (KR) 10-2013-0134313

(51) Int. Cl. G11C 7/12; G11C 7/06

(52) U.S. Cl. CPC G11C 7/12; G11C 7/06
USPC 365/202; 365/203

(57) ABSTRACT

Semiconductor devices are provided. The semiconductor device includes a first pre-charge element and a second pre-charge element. The first pre-charge element receives a first pre-charge signal to pre-charge a first bit line to have a first pre-charge voltage signal. The second pre-charge element receives a second pre-charge signal to pre-charge a second bit line to have a second pre-charge voltage signal. The second pre-charge signal is enabled earlier than the first pre-charge signal in the event that a data stored in a memory cell of a first cell block is loaded on the first bit line.

### CROSS-REFERENCE TO RELATED APPLICATION

The present application claims priority under 35 U.S.C 119(a) to Korean Application No. 10-2013-0134313, filed on Nov. 6, 2013, in the Korean Intellectual Property Office, which is incorporated herein by reference in its entirety as set forth in full.

### BACKGROUND

1. Technical Field

Embodiments described below relate to semiconductor devices.

2. Related Art

In the electronics industry, low cost, compact and highly integrated semiconductor devices are increasingly in demand with the development of computer systems and electronic communication systems.

In general, a semiconductor device such as a dynamic random access memory (DRAM) device may include a cell block in which data are stored, and the cell block may include a plurality of memory cells located at intersections of word lines and bit lines that are arrayed in a matrix form. Each of the memory cells may include a single NMOS transistor and a single capacitor and may store a single data therein.

An operation of a typical DRAM device will be described briefly hereinafter.

First, if a complementary (e.g., inversed) row address strobe (/RAS) signal is enabled during an active operation (i.e., an active mode), a row address signal inputted through a row address buffer may be decoded to execute a row decoding operation that selects one of word lines in a cell block. In such a case, if data in memory cells electrically connected to the selected word line are loaded on bit line pairs including bit lines and complementary bit lines, a signal informing of a point of time that sense amplifiers operate may be enabled to drive a sense amplifier drive circuit of a cell block which is selected by the row address signal. In addition, bias potentials of the sense amplifiers may be changed into a core potential (Vcore) or a ground potential (Vss) by the sense amplifier drive circuit, and the sense amplifiers may operate. If the sense amplifiers operate, a small potential difference between a bit line potential and a complementary bit line potential may be amplified to have a large potential difference. Subsequently, a column decoder selected by column address signals may turn on column transfer transistors to transmit data on the bit lines to data bus lines connected to output pads.

That is, the bit line pairs may be pre-charged in a standby mode in advance of the active mode, and the data of the memory cells may be transmitted to the bit line pairs if the active mode starts. Further, if the sense amplifiers operate, the potentials of the bit line pairs may be amplified to have the core potential (Vcore) or the ground potential (Vss).

In order that the DRAM device is put in an idle state after last data are inputted thereto, a pre-charge command signal has to be generated. A generation moment of the pre-charge command signal may have relation with a write recovery time tWR. The write recovery time tWR may be a parameter that relates to a data write time. Moreover, in order that next data are inputted into the memory cells after the pre-charge state, the active mode has to be executed. In such a case, a generation moment of an active command signal may have relation with a pre-charge time tRP. The pre-charge time tRP may be a parameter that relates to a time it takes the DRAM device to enter the standby mode after the pre-charge command signal is generated.

### SUMMARY

According to various embodiments, a semiconductor device includes a first pre-charge element and a second pre-charge element. The first pre-charge element receives a first pre-charge signal to pre-charge a first bit line to have a first pre-charge voltage signal. The second pre-charge element receives a second pre-charge signal to pre-charge a second bit line to have a second pre-charge voltage signal. The second pre-charge signal is enabled earlier than the first pre-charge signal in the event that a data stored in a memory cell of a first cell block is loaded on the first bit line.

According to various embodiments, a semiconductor device includes a pre-charge control signal generator suitable for generating first and second pre-charge signals which are asynchronously enabled, a first pre-charge element suitable for receiving the first pre-charge signal to pre-charge a first bit line to have a first pre-charge voltage signal, and a second pre-charge element suitable for receiving the second pre-charge signal to pre-charge a second bit line to have a second pre-charge voltage signal.

According to various embodiments, a semiconductor device includes a pre-charge control signal generator suitable for generating first and second pre-charge signals which are asynchronously enabled, a first pre-charge element suitable for receiving the first pre-charge signal to pre-charge a first bit line to have a first pre-charge voltage signal, a second pre-charge element suitable for receiving the second pre-charge signal to pre-charge a second bit line to have a second pre-charge voltage signal, a sense amplifier configured to sense and amplify a data loaded on the first bit line or the second bit line, an equalizer suitable for being turned on to electrically couple the first bit line to the second bit line, and a switch element suitable for being turned on to electrically couple the first and second bit lines to respective ones of input/output (I/O) line pairs.

In an embodiment, a system comprises: a processor; a controller configured to receive a request and a data from the processor; and a memory unit configured to receive the request and the data from the controller, wherein the memory unit includes: a first pre-charge element suitable for receiving a first pre-charge signal to pre-charge the first bit line to have a first pre-charge voltage signal; and a second pre-charge element suitable for receiving a second pre-charge signal to pre-charge the second bit line to have a second pre-charge voltage signal, wherein the second pre-charge signal is enabled earlier than the first pre-charge signal in the event that a data stored in a memory cell of a first cell block is loaded on the first bit line.

### BRIEF DESCRIPTION OF THE DRAWINGS

Embodiments will become more apparent in view of the attached drawings and accompanying detailed description, in which:

FIG. 1 is a block diagram illustrating a configuration of a semiconductor device according to an embodiment; and

FIGS. 2 to 5 are timing diagrams illustrating an operation of the semiconductor device shown in FIG. 1; and

FIG. 6 illustrates a block diagram of a system employing a memory controller circuit in an embodiment.

### DETAILED DESCRIPTION OF THE EMBODIMENTS

Various embodiments will be described hereinafter with reference to the accompanying drawings. However, the embodiments described herein are for illustrative purposes only.

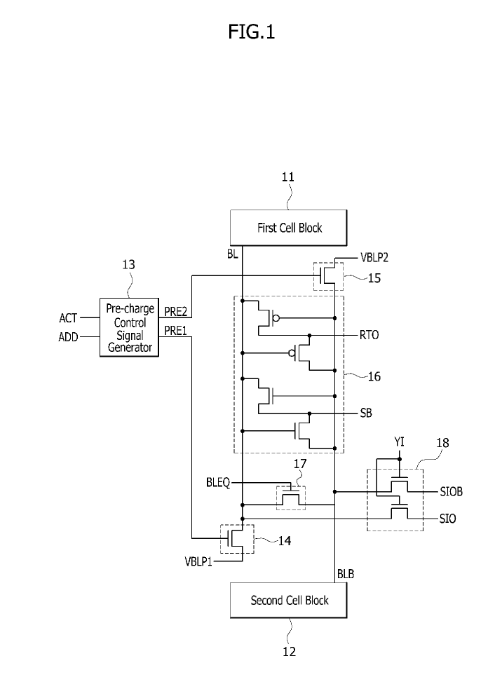

Referring to FIG. 1, a semiconductor device according to an embodiment may include a first cell block 11, a second cell block 12, a pre-charge control signal generator 13, a first pre-charge element 14, a second pre-charge element 15, a sense amplifier 16, an equalizer 17 and a switch element 18.

The pre-charge control signal generator 13 may generate a first pre-charge signal PRE1 and a second pre-charge signal PRE2 which are enabled in response to an address signal ADD in an active mode that is executed by an enabled active signal ACT. The pre-charge control signal generator 13 may generate the first pre-charge signal PRE1 and the second pre-charge signal PRE2 which may be asynchronously enabled in response to the address signal ADD in the active mode. The pre-charge control signal generator 13 may sequentially generate the second pre-charge signal PRE2 enabled to have a logic “high” level and the first pre-charge signal PRE1 enabled to have a logic “high” level if the address signal ADD for accessing memory cells (not shown) included in the first cell block 11 is inputted thereto in the active mode. Further, the pre-charge control signal generator 13 may sequentially generate the first pre-charge signal PRE1 enabled to have a logic “high” level and the second pre-charge signal PRE2 enabled to have a logic “high” level if the address signal ADD for accessing memory cells (not shown) included in the second cell block 12 is inputted thereto in the active mode.

The first pre-charge element 14 may be turned on to pre-charge a first bit line BL to a level of a first pre-charge voltage signal VBLP1 if the first pre-charge signal PRE1 is enabled to have a logic “high” level is inputted thereto. The first pre-charge element 14 may be suitable for being electrically coupled to the first bit line BL and receive the first pre-charge signal PRE1 to pre-charge the first bit line BL to have the first pre-charge voltage signal VBLP1. The second pre-charge element 15 may be turned on to pre-charge a second bit line BLB to a level of a second pre-charge voltage signal VBLP2 if the second pre-charge signal PRE2 is enabled to have a logic “high” level is inputted thereto. The second pre-charge element 15 may be suitable for being electrically coupled to the second bit line BLB and for receiving the second pre-charge signal PRE2 to pre-charge the second bit line BLB to have the second pre-charge voltage signal VBLP2. The first and second pre-charge voltage signals VBLP1 and VBLP2 may be set to have the same level or to have different levels from each other according to the embodiments. The second bit line BLB may be a complementary bit line of the first bit line BL.

The sense amplifier 16 may be coupled between the first bit line BL and the second bit line BLB to sense and amplify a voltage difference between the first bit line BL and the second bit line BLB. The sense amplifier 16 may be configured to sense and amplify a data loaded on the first bit line BL and the second bit line BLB. In an embodiment, the sense amplifier 16 may be realized using a cross-coupled latch circuit.

The equalizer 17 may be coupled between the first bit line BL and the second bit line BLB and may be turned on in response to a bit line equalization signal BLEQ to electrically couple the first bit line BL to the second bit line BLB. That is, the equalizer 17 may be turned on in response to a bit line equalization signal BLEQ to equalize the levels of the first and second bit lines BL and BLB. The bit line equalization signal BLEQ may be enabled to have a logic “high” level such that the levels of the first and second bit lines BL and BLB are equalized to have the same potential in a standby mode.

The switch element 18 may be turned on in response to an output selection signal YI enabled in a column mode to electrically couple the first and second bit lines BL and BLB to respective ones of input/output (I/O) line pairs SIO and SIOB. The column mode may include a write mode that data are inputted to the first and second bit lines BL and BLB through the I/O line pairs SIO and SIOB and a read mode that data are outputted to the I/O line pairs SIO and SIOB through the first and second bit lines BL and BLB.

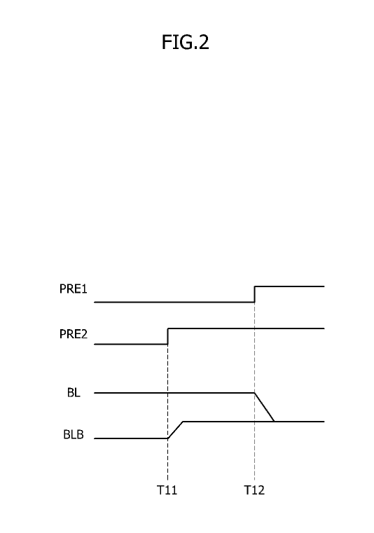

An operation of the semiconductor device having the aforementioned configuration will be described hereinafter with reference to FIGS. 2 to 5 in conjunction with an example in which a logic “high” level data and a logic “low” level data stored in the memory cells (not shown) of the first cell block 11 are loaded on the first bit line BL and an example in which a logic “high” level data and a logic “low” level data stored in the memory cells (not shown) of the second cell block 12 are loaded on the second bit line BLB.

Referring to FIG. 2, in the event that a logic “high” level data stored in a memory cell of the first cell block 11 is loaded on the first bit line BL, the pre-charge control signal generator 13 may sequentially generate the second pre-charge signal PRE2 enabled to have a logic “high” level and the first pre-charge signal PRE1 enabled to have a logic “high” level at a point of time “T11” and at a point of time “T12”, respectively. The second bit line BLB whose level is amplified to have a logic “low” level may be pre-charged by the second pre-charge signal PRE2 having a logic “high” level to have a level of the second pre-charge voltage signal VBLP2 at the point of time “T11”. The first bit line BL whose level is amplified to have a logic “high” level may be pre-charged by the first pre-charge signal PRE1 having a logic “high” level to have a level of the first pre-charge voltage signal VBLP1 at the point of time “T12”. According to an embodiment, the first and second pre-charge voltage signals VBLP1 and VBLP2 may be set to have the same level. However, in various embodiments, the first and second pre-charge voltage signals VBLP1 and VBLP2 may be set to have different levels.

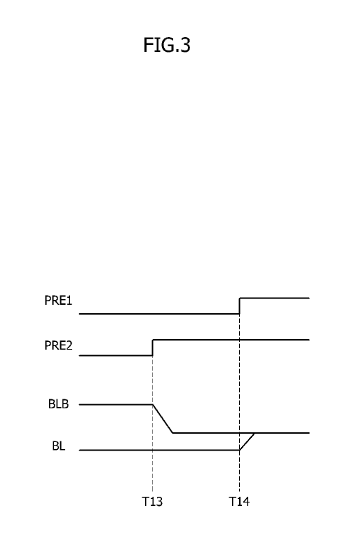

Referring to FIG. 3, in the event that a logic “low” level data stored in a memory cell of the first cell block 11 is loaded on the first bit line BL, the pre-charge control signal generator 13 may sequentially generate the second pre-charge signal PRE2 enabled to have a logic “high” level and the first pre-charge signal PRE1 enabled to have a logic “high” level at a point of time “T13” and at a point of time “T14”, respectively. The second bit line BLB whose level is amplified to have a logic “high” level may be pre-charged by the second pre-charge signal PRE2 having a logic “high” level to have a level of the second pre-charge voltage signal VBLP2 at the point of time “T13”. The first bit line BL whose level is amplified to have a logic “low” level may be pre-charged by the first pre-charge signal PRE1 having a logic “high” level to have a level of the first pre-charge voltage signal VBLP1 at the point of time “T14”.

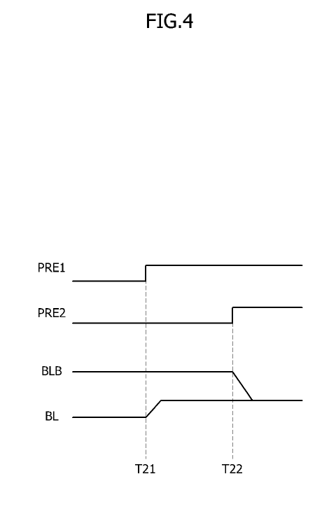

Referring to FIG. 4, in the event that a logic “high” level data stored in a memory cell of the second cell block 12 is loaded on the second bit line BLB, the pre-charge control signal generator 13 may sequentially generate the first pre-charge signal PRE1 enabled to have a logic “high” level and the second pre-charge signal PRE2 enabled to have a logic “high” level at a point of time “T21” and at a point of time “T22”, respectively. The first bit line BL whose level is amplified to have a logic “low” level may be pre-charged by the first pre-charge signal PRE1 having a logic “high” level to have a level of the first pre-charge voltage signal VBLP1 at the point of time “T21”. The second bit line BLB whose level is amplified to have a logic “high” level may be pre-charged by the second pre-charge signal PRE2 having a logic “high” level to have a level of the second pre-charge voltage signal VBLP2 at the point of time “T22”.

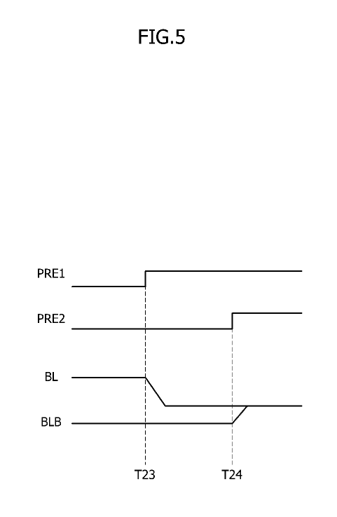

Referring to FIG. 5, in the event that a logic “low” level data stored in a memory cell of the second cell block 12 is loaded on the second bit line BLB, the pre-charge control signal generator 13 may sequentially generate the first pre-charge signal PRE1 enabled to have a logic “high” level and the second pre-charge signal PRE2 enabled to have a logic “high” level at a point of time “T23” and at a point of time “T24”, respectively. The first bit line BL whose level is amplified to have a logic “high” level may be pre-charged by the first pre-charge signal PRE1 having a logic “high” level to have a level of the first pre-charge voltage signal VBLP1 at the point of time “T23”. The second bit line BLB whose level is amplified to have a logic “low” level may be pre-charged by the second pre-charge signal PRE2 having a logic “high” level to have a level of the second pre-charge voltage signal VBLP2 at the point of time “T24”.

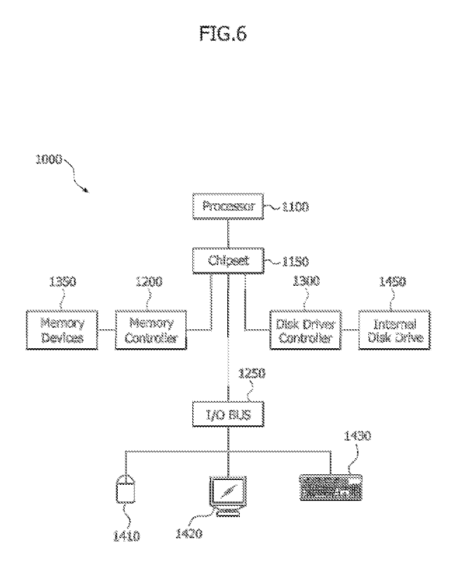

Referring to FIG. 6, a system 1000 may include one or more processors 1100. The processor 1100 may be used individually in combination with other processors. A chipset 1150 may be operably coupled to the processor 1100. The chipset 1150 is a communication pathway for signals between the processor 1100 and other components of the system 1000. The system 1000 may include a memory controller 1200, an input/output (“I/O”) bus 1250 and a disk drive controller 1300. Depending on the configuration of the system 1000, any one of a number of different signals may be transmitted through the chipset 1150.

The memory controller 1200 may be operably coupled to the chipset 1150. The memory controller 1200 may be electrically coupled to one or more memory devices 1350. The memory controller 1200 can receive a request provided from the processor 1100 through the chipset 1150. The memory device 1350 may correspond to the semiconductor device described above.

The chipset 1150 may also be electrically coupled to the I/O bus 1250. The I/O bus 1250 may serve as a communication pathway for signals from the chipset 1150 to the I/O devices 1410, 1420 and 1430. The I/O devices 1410, 1420 and 1430 may include a mouse 1410, a video display 1420, or a keyboard 1430. The I/O bus 1250 may employ any one of a number of communications protocols to communicate with the I/O devices 1410, 1420 and 1430.

The disk drive controller 1300 may also be electrically coupled to the chipset 1150. The disk drive controller 1300 may serve as the communication pathway between the chipset 1150 and one or more internal disk drives 1450. The internal disk drive 1450 and disk drive controller 1300 may communicate with each other or with the chipset 1150 using virtually any type of communication protocol, including all of those mentioned above with regard to the I/O bus 1250.

As described above, the semiconductor device according to embodiments may asynchronously pre-charge the first bit line BL on which a data stored in a memory cell of the first cell block 11 is loaded and the second bit line BLB on which a data stored in a memory cell of the second cell block 12 is loaded, thereby improving a write characteristic and a pre-charge characteristic thereof. That is, in the event that a data stored in a memory cell of the first cell block 11 is loaded on the first bit line BL, the semiconductor device may pre-charge the second bit line BLB earlier than the first bit line BL to increase a pre-charge time tRP and to improve the pre-charge characteristic and may pre-charge the first bit line BL later than the second bit line BLB to increase a write recovery time tWR and to improve the write characteristic. Further, in the event that a data stored in a memory cell of the second cell block 12 is loaded on the second bit line BLB, the semiconductor device may pre-charge the first bit line BL earlier than the second bit line BLB to increase a pre-charge time tRP and to improve the pre-charge characteristic and may pre-charge the second bit line BLB later than the first bit line BL to increase a write recovery time tWR and to improve the write characteristic.

What is claimed is:

1. A semiconductor device comprising:
a first pre-charge element suitable for receiving a first pre-charge signal to pre-charge a first bit line to have a first pre-charge voltage signal; and
a second pre-charge element suitable for receiving a second pre-charge signal to pre-charge a second bit line to have a second pre-charge voltage signal,
wherein the second pre-charge signal is enabled earlier than the first pre-charge signal in the event that a data stored in a memory cell of a first cell block is loaded on the first bit line.

2. The semiconductor device of claim 1, further comprising:
a pre-charge control signal generator suitable for generating the first and second pre-charge signals in response to an address signal in an active mode.

3. The semiconductor device of claim 2, wherein the pre-charge control signal generator generates the first and second pre-charge signals which are asynchronously enabled in response to the address signal in the active mode.

4. The semiconductor device of claim 3, wherein the first pre-charge element is turned on to have a first pre-charge voltage signal when the first pre-charge signal is enabled.

5. The semiconductor device of claim 4, wherein the second pre-charge element is turned on to have a second pre-charge voltage signal when the second pre-charge signal is enabled.

6. The semiconductor device of claim 3, wherein the pre-charge control signal generator sequentially generates the second pre-charge signal and the first pre-charge signal when the address signal for accessing memory cells included in the first cell block is inputted.

7. The semiconductor device of claim 6, wherein the pre-charge control signal generator sequentially generates the first pre-charge signal and the second pre-charge signal when the address signal for accessing memory cells included in a second cell block is inputted.

8. The semiconductor device of claim 1, wherein the first and second pre-charge voltage signals are configured to have the same level.

9. The semiconductor device of claim 1, further comprising:
a sense amplifier configured to sense and amplify a data loaded on the first bit line or the second bit line.

10. The semiconductor device of claim 1, further comprising:
an equalizer suitable for being turned on to electrically couple the first bit line and the second bit line to each other.

11. The semiconductor device of claim 1, further comprising:
a switch element suitable for being turned on in response to an output selection signal to electrically couple the first and second bit lines to respective ones of input/output (I/O) line pairs.

12. A semiconductor device comprising:
a pre-charge control signal generator suitable for generating first and second pre-charge signals which are asynchronously enabled;
a first pre-charge element suitable for receiving the first pre-charge signal to pre-charge a first bit line to have a first pre-charge voltage signal; and
a second pre-charge element suitable for receiving the second pre-charge signal to pre-charge a second bit line to have a second pre-charge voltage signal.

13. The semiconductor device of claim 12, wherein the first pre-charge element is turned on to have the first pre-charge voltage signal when the first pre-charge signal is enabled.

14. The semiconductor device of claim 13, wherein the second pre-charge element is turned on to have the second pre-charge voltage signal when the second pre-charge signal is enabled.

15. The semiconductor device of claim 12, wherein the pre-charge control signal generator sequentially generates the second pre-charge signal and the first pre-charge signal if the address signal for accessing memory cells in a first cell block is inputted.

16. The semiconductor device of claim 15, wherein the pre-charge control signal generator sequentially generates the first pre-charge signal and the second pre-charge signal if the address signal for accessing memory cells included in a second cell block is inputted.

17. The semiconductor device of claim 12, wherein the first and second pre-charge voltage signals are configured to be at the same level.

18. The semiconductor device of claim 12, further comprising:
a sense amplifier configured to sense and amplify a data loaded on the first bit line or the second bit line.

19. The semiconductor device of claim 12, further comprising:
an equalizer suitable for being turned on to electrically couple the first bit line to the second bit line; and
a switch element suitable for being turned on in response to an output selection signal to electrically couple the first and second bit lines to respective ones of input/output (I/O) line pairs.

20. A semiconductor device comprising:
a pre-charge control signal generator suitable for generating first and second pre-charge signals which are asynchronously enabled;
a first pre-charge element suitable for being suitable for receiving the first pre-charge signal to pre-charge a first bit line to have a first pre-charge voltage signal;
a second pre-charge element suitable for receiving the second pre-charge signal to pre-charge the second bit line to have a second pre-charge voltage signal;
a sense amplifier configured to sense and amplify a data loaded on the first bit line or the second bit line;
an equalizer suitable for being turned on to electrically couple the first bit line to the second bit line; and
a switch element suitable for being turned on to electrically couple the first and second bit lines to respective ones of input/output (I/O) line pairs.
